(19) United States
(12) Patent Application Publication
(10) Pub. No.: US 2008/0180887 A1
(43) Pub. Date: Jul. 31, 2008

(54) Attachment of an electrical appliance to a holding plate, in particular to a switch panel, and an adapter for such attachment

(75) Inventor: Rainer Hauser, Numberg (DE)

Correspondence Address: HARNESS, DICKEY & PIERCE, P.L.C., P.O.BOX 8910, RESTON, VA, 20195, US

(73) Assignee: SIEMENS AKTIENGESELLSCHAFT

(21) Appl. No.: 12/010,245

(22) Filed: Jan. 23, 2008

(30) Foreign Application Priority Data
Jan. 25, 2007 (DE) 10 2007 004 905.8

(51) Int. Cl. H05K 7/00

(52) U.S. Cl. 361/679

(57) ABSTRACT

An attachment is disclosed for an electrical appliance to a holding plate, for example to a switch panel, as well as to an adapter for such an attachment, which for this purpose has an aperture opening into which the appliance, which has a front panel, can be inserted. In at least one embodiment, in order to allow attachment of one and the same appliance with the aperture openings having mutually exclusive cross-sectional shapes, it is proposed that an adapter is provided, formed from two parts that can be connected to one another, and arranged between the front panel and the appliance. In at least one embodiment, the front part is fitted with the front panel on one side and is attached to the holding plate on the other side, with this part having at least one connecting element, which is accessible via the aperture opening. The rear part of the adapter is attached to the appliance rather than the front panel, and, for connection to the front part, has at least one connecting element which is complementary thereto.

### PRIORITY STATEMENT

The present application hereby claims priority under 35 U.S.C. §119 on German patent application number DE 10 2007 004 905.8 filed Jan. 25, 2007, the entire contents of which is hereby incorporated herein by reference.

### FIELD

Embodiments of the invention generally relate to an attachment for an electrical appliance to a holding plate, for example to a switch panel, and/or to an adapter for such attachment.

### BACKGROUND

Attachments of electrical appliances to switch panels are generally known. Aperture openings are provided for this purpose in the switch panels, into which the appliance is inserted, for example from the front, and is then attached. In particular, appliances exist which have a removable front panel which has a display on it. For electrical connection to the appliance, electrical contacts are located on the rear face of the front panel and are detachably connected to corresponding contacts on the appliance, in the operating status.

The aperture openings in the switch panel are generally DIN-96 cross-sectional shapes, that is to say the aperture opening is a square with a side length of 92 mm. Another cross-sectional shape, which is used in particular in the USA, is the ANSI-4″ cross-sectional shape, which has a circular aperture opening with a diameter of four inches (in addition to four additional aperture holes for screws). The associated appliances have the appropriate cross-sectional shape, in each case when seen from the rear.

The two cross-sectional shapes that are mentioned have dimensions such that an appliance which is designed for DIN-96 aperture openings cannot be inserted into an ANSI-4″ aperture opening. The opposite is also true.

### SUMMARY

In at least one embodiment of the invention, attachment of one and the same appliance is permitted with mutually exclusive cross-sectional shapes of the aperture openings.

With regard to the attachment, in at least one embodiment the solution provides for an adapter to be provided, be formed from two parts that can be connected to one another, and be arranged between the front panel and the appliance, for the front part of the adapter to be fitted with the front panel on one side and to be attached to the holding plate on the other side, with this part having at least one connecting element, which is accessible via the aperture opening, on the side facing the holding plate, and for the rear part of the adapter to be attached to the appliance rather than the front panel, and, for connection to the front part, to have at least one connecting element which is complementary thereto. The advantage of this attachment is such that virtually any appliance is made compatible with an available standard housing by means of such attachment to the respective other cross-sectional shape. The actual front panel remains unchanged; the internal electronics may be the same for both cross-sectional shapes.

One simple attachment, in at least one embodiment, provides for the front part to be in the form of a depression into which the rear part, which is in the form of a projection, can be inserted through the aperture opening.

Simple assembly, in at least one embodiment, is achieved by the complementary connecting elements latching to one another during insertion.

Simple maintenance of the detachable contact is proposed by the front part having a contact connecting element which connects the contacts on the front panel to those on the appliance.

With regard to the adapter, the solution provides for this adapter to be formed from two parts that can be connected to one another, for the front part to be fitted with the front panel on one side and to be attached to the holding plate on the other side, furthermore having a connecting element, which is accessible via the aperture opening, on the side facing the holding plate, and for the rear part to be attached to the appliance rather than the front panel, and, for connection to the front part, to have a connecting element which is complementary thereto.

### BRIEF DESCRIPTION OF THE DRAWINGS

Embodiments of the invention will be described in more detail in the following text with reference to the drawings, in which:

FIG. 1 shows an attachment of an electrical appliance to a switch panel by way of an adapter,

FIG. 2 shows the rear part of the adapter,

FIG. 3 shows the front part of the adapter, seen from the front, and

FIG. 4 shows the front part of the adapter, seen from the rear.

### DETAILED DESCRIPTION OF THE EXAMPLE EMBODIMENTS

The terminology used herein is for the purpose of describing particular embodiments only and is not intended to be limiting of the present invention. As used herein, the singular forms “a”, “an”, and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

In describing example embodiments illustrated in the drawings, specific terminology is employed for the sake of clarity. However, the disclosure of this patent specification is not intended to be limited to the specific terminology so selected and it is to be understood that each specific element includes all technical equivalents that operate in a similar manner.

Referencing the drawings, wherein like reference numerals designate identical or corresponding parts throughout the several views, example embodiments of the present patent application are hereafter described. Like numbers refer to like elements throughout. As used herein, the terms “and/or” and “at least one of” include any and all combinations of one or more of the associated listed items.

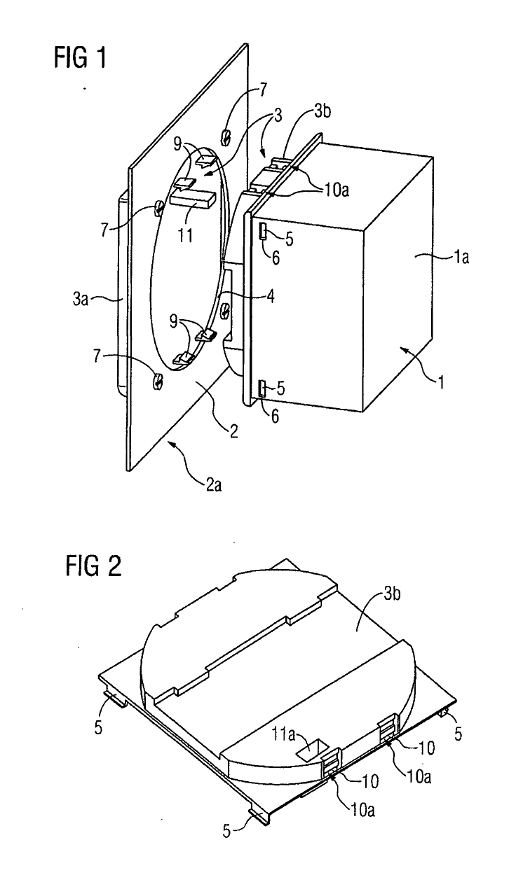

FIG. 1 shows, schematically, the attachment of an electrical appliance 1 to a switch panel 2 as a holding plate 2a by way of an adapter 3 which includes a front part 3a and a rear part 3b, in which case the two parts 3a, 3b can be connected to one another.

The appliance 1 is an appliance with a removable front panel (not shown) on which electronic components, which are likewise not shown, in particular a display, are arranged. On its rear face, the front panel is fitted with appropriate electrical contacts, which rest on appropriate contacts on the front face of the appliance 1 and are thus detachably connected to these contacts.

As shown in FIG. 1, the housing 1a of the appliance 1 has a square cross-section with an edge length of 92 mm. This corresponds to the DIN-96 cross-sectional shape, that is to say the appliance 1 can be inserted with its housing 1a into an opening with the DIN-96 cross-sectional shape. In contrast, the switch panel 2 in this case has a circular aperture opening 4 with an ANSI-4″ cross-sectional shape. Because of the dimensions of the two cross-sectional shapes, the appliance 1 cannot be inserted directly into the aperture opening 4, but only with an adapter 3.

In the case of the appliance 1 shown in FIG. 1, the front panel has been removed and, in its place, the rear adapter part 3b is seated on the front face of the appliance 1. For attachment to the housing 1a of the appliance 1, hooks 5 which are provided on the adapter part 3a engage in corresponding cutouts 6, being latched to one another.

The front part 3a of the adapter 3 is, in contrast, mounted on the front face of the switch panel 2 by way of screws 7, completely covering the aperture opening 4. The adapter part 3a is fitted with the front face of the appliance 1.

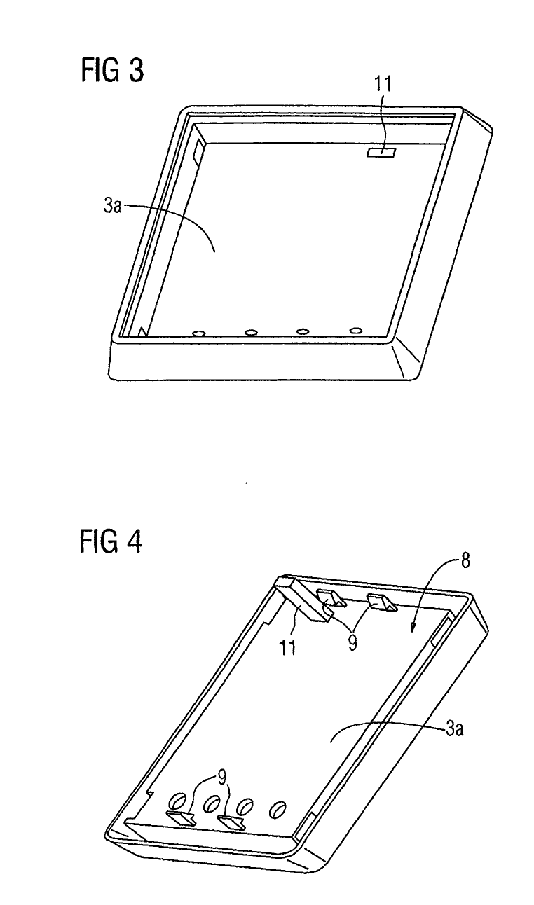

In order to connect the two adapter parts 3a, 3b, and therefore the appliance 1, to the switch panel 2, the projection-like adapter part 3b is inserted into the aperture opening 4 and a depression 8, located behind it, in the front part 3a (see FIG. 3). The projection-like rear adapter part 3b is in this case designed to be complementary to the combination of the depression 8 and the aperture opening 4, this combination in this case interlocking with the front part 3a. On the side facing the switch panel 2, the front part 3a has connecting elements 9, which are accessible via the aperture opening 4 and are in the form of hooks which, during insertion of the rear part 3b, latch with corresponding depressions and apertures 10 as essentially complementary connecting elements 10a for the part 3b, engaging behind them.

The contacts on the front panel are connected to those on the appliance 1 via a schematically illustrated contact connecting element 11, with the front part 3a having a bushing 11a for this purpose.

FIG. 2 shows the rear part 3b of the adapter 3 from the front, FIG. 3 shows the front part 3a from the front, and FIG. 4 shows it from the rear.

Further, elements and/or features of different example embodiments may be combined with each other and/or substituted for each other within the scope of this disclosure and appended claims.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. An attachment for an electrical appliance to a holding plate, the holding plate including an aperture opening into which the electrical appliance is insertable, the electrical appliance including a removable front panel with electronic components, the front panel being fitted on its rear face with electrical contacts which are detachably connected to corresponding contacts on the electrical appliance, the attachment comprising:
an adapter, formed from two parts connectible to one another, arranged between the front panel and the electrical appliance, a front part of the adapter being fitted with the front panel on one side and being attached to the holding plate on another side, the front part including at least one connecting element which is accessible via the aperture opening on the side facing the holding plate, and a rear part of the adapter being attached to the electrical appliance and including at least one connecting element, complementary to the at least one connecting element of the front part, for connection to the front part.

2. The attachment as claimed in claim 1, wherein the front part is a holder in the form of a depression into which the rear part, in the form of a projection, is insertable through the aperture opening.

3. The attachment as claimed in claim 1, wherein the at least one complementary connecting element includes at least two complementary connecting elements latched to one another during insertion.

4. The attachment as claimed in claim 1, wherein the front part includes a contact connecting element to connect the contacts on the front panel to the contacts on the electrical appliance.

5. An adapter for attachment of an electrical appliance to a holding plate, the holding plate including an aperture opening into which the electrical appliance is insertable, the electrical appliance including a removable front panel with electronic components, the front panel being fitted on its rear face with electrical contacts which are detachably connected to corresponding contacts on the electrical appliance, the adapter comprising:
a front part, fitted with the front panel on one side and being attached to the holding plate on another side, including a connecting element, accessible via the aperture opening, on the one of the one and another sides facing the holding plate; and
a rear part, attached to the electrical appliance and including a connecting element, complementary to the connecting element of the front part, to connect to the front part.

6. The attachment of claim 1, wherein the holding plate is a switch panel.

7. The attachment as claimed in claim 2, wherein the at least one complementary connecting element includes at least two complementary connecting elements latched to one another during insertion.

8. The attachment of claim 1, wherein the front panel of the electrical appliance includes a display.

9. The attachment as claimed in claim 2, wherein the front part includes a contact connecting element to connect the contacts on the front panel to the contacts on the electrical appliance.

10. The attachment as claimed in claim 3, wherein the front part includes a contact connecting element to connect the contacts on the front panel to the contacts on the electrical appliance.

11. The attachment of claim 5, wherein the holding plate is a switch panel.

12. The attachment of claim 5, wherein the front panel of the electrical appliance includes a display.
